(19) United States
(12) Patent Application Publication
(10) Pub. No.: US 2023/0010446 A1
(43) Pub. Date: Jan. 12, 2023

(54) METHOD OF MANUFACTURING HIGH CAPACITANCE ANODE AND CATHODE FILMS OF CAPACITOR

(71) Applicant: TRUSVAL TECHNOLOGY CO., LTD., MIAOLI COUNTY (TW)

(72) Inventor: SHIH-PAO CHIEN, MIAOLI COUNTY (TW)

(21) Appl. No.: 17/371,634

(22) Filed: Jul. 9, 2021

(51) Int. Cl. C23C 14/06; H01G 9/045; C23C 14/16; C23C 14/58

(52) U.S. Cl. CPC C23C 14/0676; H01G 9/045; C23C 14/165; C23C 14/58; C23C 14/0641

(57) ABSTRACT

A method of manufacturing high capacitance anode and cathode films of capacitors is revealed. Perform sputter deposition on a cathode aluminum foil in a vacuum chamber to form a cathode metal layer which is a titanium layer on a surface of the cathode aluminum foil. Then titanium continuously reacts with nitrogen to form cathode columnar crystal deposition on a surface of the cathode metal layer and get a cathode film. Perform sputter deposition on an anode aluminum foil in a vacuum chamber to form an anode metal layer which is a titanium layer on a surface of the anode aluminum foil. Then titanium continuously reacts with oxygen and nitrogen to form anode columnar crystal deposition on a surface of the anode metal layer and get an anode film. Next use the cathode and anode films with high capacitance to form cathode and anode electrodes of the capacitor.

### BACKGROUND OF THE INVENTION

### Field of the Invention

The present invention relates to a method of manufacturing anode and cathode films of capacitors, especially to a method of manufacturing high capacitance anode and cathode films of capacitors which makes capacitors formed by the anode and cathode films manufactured more convenient to use due to high capacitance of the anode and cathode films.

### Description of Related Art

Capacitors which are passive electronic components used for storage of electrical energy in an electric filed are common on integrated circuits (ICs). The capacitors are broadly used in electronic circuits for blocking direct current while allowing alternating current to pass. In analog filter networks, they smooth the output of power supplies. In personal computer (PC) circuit, they work together with inductors for tuning radios to particular frequencies. In electric power transmission systems, they stabilize voltage and power flow.

As to conductive terminals of the capacitor, two terminals connected to and arranged at the bottom of the capacitor are directly pressed and bent outward for being used conveniently in the subsequent processes. Although the above conductive terminals of the capacitor can be connected and conducted to other electronic components as expected, the conductive terminals made of metals has the problem of low capacitance, which makes the conductive terminals inconvenient to use.

Thus there is room for improvement and there is a need to provide a method of manufacturing anode and cathode films of capacitors which makes the capacitors formed by the anode and cathode films manufactured more convenient to use.

### SUMMARY OF THE INVENTION

Therefore, it is a primary object of the present invention to provide a method of manufacturing high capacitance anode and cathode films of capacitors which makes the capacitors formed by the anode and cathode films manufactured more convenient to use due to high capacitance of the anode and cathode films.

In order to achieve the above object, a method of manufacturing high capacitance anode and cathode films of capacitors according to the present invention includes the following steps.

A. manufacturing a cathode film. Perform sputter deposition on a cathode aluminum foil in a vacuum chamber. By control of power density and temperature, a cathode metal layer which is a titanium (Ti) layer with a thickness of 10-100 nm is formed on a surface of the cathode aluminum foil. Then titanium (Ti) continuously reacts with nitrogen (N) to carry out combination and deposition and various manufacturing parameters are controlled simultaneously. Thus titanium and nitrogen form cathode columnar crystal structure on a surface of the cathode metal layer. The chemical formula of the cathode columnar crystal structure is TiₓN_{y}, wherein x≅y and x−y is no more than 15%y when x>y.

B. manufacturing an anode film. Perform sputter deposition on an anode aluminum foil in a vacuum chamber. By control of power density and temperature, an anode metal layer which is a titanium (Ti) layer with a thickness of 10-1000 nm is formed on a surface of the anode aluminum foil. Then titanium (Ti) continuously reacts with oxygen (O) and nitrogen (N) to carry out combination and deposition while various manufacturing parameters are controlled simultaneously. Thus titanium (Ti), oxygen (O), and nitrogen (N) form anode columnar crystal structure on a surface of the anode metal layer. The chemical formula of the anode columnar crystal structure is TiₓO_{2-y}N_{y}, wherein x≅1 and 0≤y≤0.3.

C. producing capacitors. Use the cathode film and the anode film in manufacturing processes of capacitors to form a cathode and an anode of the capacitor respectively.

Preferably, the sputter deposition is performed on the cathode aluminum foil with high purity and high cleanliness in a vacuum chamber by magnetron sputtering deposition equipment or multi arc and magnetron sputtering integrated equipment in the step A.

Preferably, a thickness of the cathode metal layer formed in the step A is 30-50 nm.

Preferably, a chemical formula of the cathode columnar crystal structure formed in the step A is TiₓN_{y} and x:y=1.

Preferably, the sputter deposition is carried out on the anode aluminum foil with high purity and high cleanliness in a vacuum chamber by magnetron sputtering deposition equipment or multi arc and magnetron sputtering integrated equipment in the step B.

Preferably, a thickness of the anode metal layer depends on the voltage required, equal to the product of the voltage (in volts) and 1.4 (in nm) in the step B.

Preferably, in the step B, after completing the sputter deposition, the anode aluminum foil provided with the anode metal layer and the anode columnar crystal structure is moved to a high temperature vacuum annealing furnace for annealing at a vacuum of at least 10⁻³ Mpa and the highest temperature of 550° C. for at least 8 hours. Then cool down naturally to room temperature and take out from the furnace.

Preferably, in the step B, after completing the sputter deposition, the anode aluminum foil provided with the anode metal layer and the anode columnar crystal structure is moved to a high temperature vacuum annealing furnace for annealing at a vacuum of at least 10⁻³ Mpa and the highest temperature of 550° C. for at least 8 hours. Then cool down naturally to temperature below 100° C. and take out from the furnace.

Preferably, the anode film in the step B is manufactured in a continuous manner to form a ribbon which is cut into the required size and then treated by reforming and electrochemical protection.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing a manufacturing process flow chart of an embodiment according to the present invention;

FIG. 2 is a schematic drawing showing formation of a cathode film of an embodiment according to the present invention;

FIG. 3 is a schematic drawing showing formation of an anode film of an embodiment according to the present invention.

### DETAILED DESCRIPTION OF THE PREFERRED EMBODIMENT

In order to learn technical content, features and functions of the present invention more completely and clearly, please refer to the following detailed description with reference to the accompanying figures and reference signs.

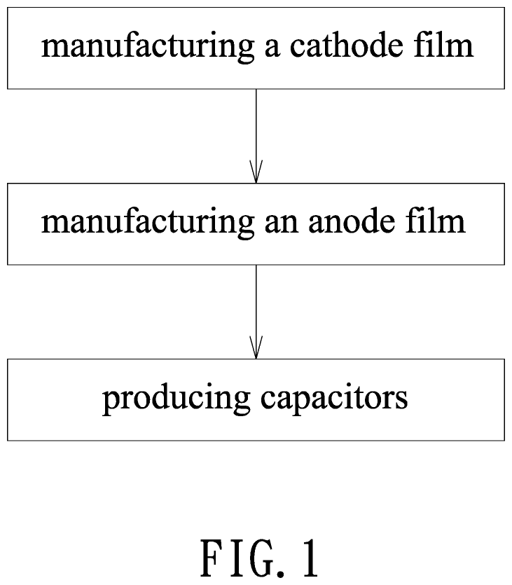

Refer to FIG. 1, a method of manufacturing high capacitance anode and cathode films of capacitors includes the following steps.

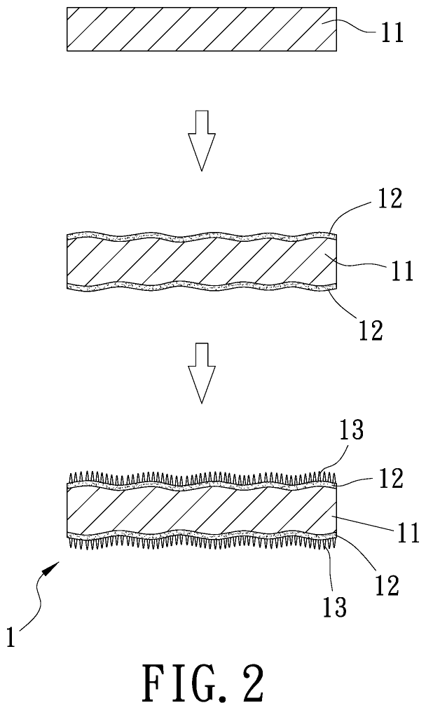

A. manufacturing a cathode film 1. Refer to FIG. 1 and FIG. 2, perform sputter deposition on a cathode aluminum foil 11 with high purity and high cleanliness in a vacuum chamber by magnetron sputtering deposition equipment or multi arc and magnetron sputtering integrated equipment and also control power density and temperature. Thus a cathode metal layer 12 which is a titanium (Ti) layer with a thickness of 10-100 nm is formed on a surface of the cathode aluminum foil 11 while the thickness of 30-50 nm is preferred. Then titanium (Ti) continuously reacts with nitrogen (N) to carry out combination and deposition while various manufacturing parameters are controlled simultaneously. Thus titanium (Ti) and nitrogen (N) form cathode columnar crystal structure 13 on a surface of the cathode metal layer 12. The chemical formula of the cathode columnar crystal structure 13 is TiₓN_{y}, wherein x≅y and x−y is no more than 15%y when x>y. That means xis larger than y but no more than 1.15y while x:y=1 is preferred.

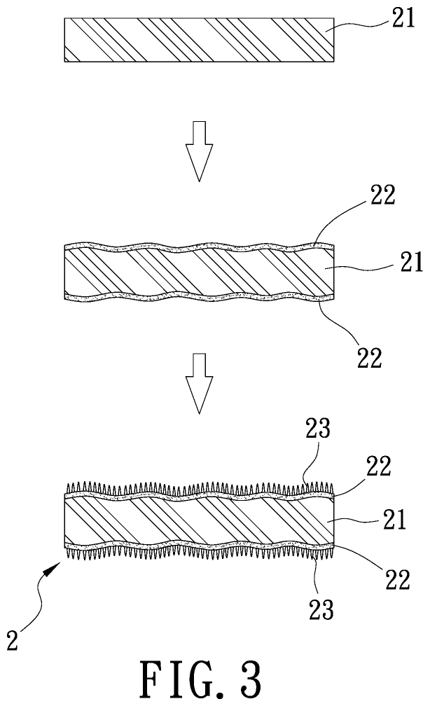

B. manufacturing an anode film 2. Also refer to FIG. 3, perform sputter deposition on an anode aluminum foil 21 with high purity and high cleanliness in a vacuum chamber by magnetron sputtering deposition equipment or multi arc and magnetron sputtering integrated equipment and also control power density and temperature. Thus an anode metal layer 22 which is a titanium (Ti) layer with a thickness of 10-1000 nm is formed on a surface of the anode aluminum foil 21. The optimal thickness of the anode metal layer 22 depends on the voltage, equal to the product of the voltage (in volts) and 1.4 (in nm) (the voltage times 1.4). For example, the thickness is 140 nm and 280 nm when the voltage is 100V and 200V respectively. Then titanium (Ti) continuously reacts with oxygen (O) and nitrogen (N) to carry out combination and deposition while various manufacturing parameters are controlled simultaneously. Thus titanium (Ti), oxygen (O), and nitrogen (N) form anode columnar crystal structure 23 on a surface of the anode metal layer 22. The chemical formula of the anode columnar crystal structure 23 is TiₓO_{2-y}N_{y}, wherein x≅1 and 0≤y≤0.3. After completing sputter deposition, the anode aluminum foil 21 with the anode metal layer 22 and the anode columnar crystal structure 23 is moved to a high temperature vacuum annealing furnace for annealing at a vacuum of at least 10⁻³ Mpa and the highest temperature of 550° C. for at least 8 hours. Then cool down naturally to temperature below 100° C. or room temperature and take a final product out from the furnace. The anode film 2 can be manufactured in a continuous manner to form a ribbon which is cut into the required size and then treated by reforming and electrochemical protection.

C. producing capacitors. Use the cathode film 1 and the anode film 2 in manufacturing processes of capacitors to form a cathode and an anode of the capacitor respectively.

Therefore, the capacitors formed by the cathode film 1 and the anode film 2 is much more convenient to use due to high capacitance of both the anode film and the cathode film.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A method of manufacturing high capacitance anode and cathode films of capacitors comprising the steps of:
A. manufacturing a cathode film: performing sputter deposition on a cathode aluminum foil in a vacuum chamber and controlling power density and temperature so that a cathode metal layer which is a titanium (Ti) layer with a thickness of 10-100 nm is formed on a surface of the cathode aluminum foil; then titanium (Ti) continuously reacting with nitrogen (N) to carry out combination and deposition while controlling various manufacturing parameters simultaneously to form cathode columnar crystal structure on a surface of the cathode metal layer; chemical formula of the cathode columnar crystal structure is TiₓN_{y}, wherein x≅y and x−y is no more than 15%y when x>y;
B. manufacturing an anode film: performing sputter deposition on an anode aluminum foil in a vacuum chamber and controlling power density and temperature so that an anode metal layer which is a titanium (Ti) layer with a thickness of 10-1000 nm is formed on a surface of the anode aluminum foil; then titanium (Ti) continuously reacting with oxygen (O) and nitrogen (N) to carry out combination and deposition while controlling manufacturing parameters simultaneously to form anode columnar crystal structure on a surface of the anode metal layer; chemical formula of the anode columnar crystal structure is TiₓO_{2-y}N_{y}, wherein x≅1 and 0≤y≤0.3;
C. producing capacitors: using the cathode film and the anode film in manufacturing processes of capacitors to form a cathode and an anode of the capacitor respectively.

2. The method as claimed in claim 1, wherein magnetron sputtering deposition equipment or multi arc and magnetron sputtering integrated equipment is used to perform the sputter deposition on the cathode aluminum foil with high purity and high cleanliness in a vacuum chamber in the step A.

3. The method as claimed in claim 1, wherein a thickness of the cathode metal layer formed in the step A is 30-50 nm.

4. The method as claimed in claim 1, wherein a chemical formula of the cathode columnar crystal structure formed in the step A is TiₓN_{y} and x: y=1 .

5. The method as claimed in claim 1, wherein magnetron sputtering deposition equipment or multi arc and magnetron sputtering integrated equipment is used to perform the sputter deposition on the anode aluminum foil with high purity and high cleanliness in a vacuum chamber in the step B.

6. The method as claimed in claim 1, wherein a thickness of the anode metal layer depends on a voltage required, equal to product of the voltage (in volts) and 1.4 (in nm) in the step B.

7. The method as claimed in claim 1, wherein the anode film manufactured in the step B is manufactured in a continuous manner to form a ribbon which is cut into required size and then treated by reforming and electrochemical protection.

8. The method as claimed in claim 1, wherein in the step B, after completing the sputter deposition, the anode aluminum foil provided with the anode metal layer and the anode columnar crystal structure is moved to a high temperature vacuum annealing furnace for annealing at a vacuum of at least 10⁻³ Mpa and the highest temperature of 550° C. for at least 8 hours; then cool down naturally to room temperature and take out from the furnace.

9. The method as claimed in claim 8, wherein the anode film manufactured in the step B is manufactured in a continuous manner to form a ribbon which is cut into required size and then treated by reforming and electrochemical protection.

10. The method as claimed in claim 1, wherein in the step B, after completing the sputter deposition, the anode aluminum foil provided with the anode metal layer and the anode columnar crystal structure is moved to a high temperature vacuum annealing furnace for annealing at a vacuum of at least 10⁻³ Mpa and the highest temperature of 550° C. for at least 8 hours; then cool down naturally to temperature below 100° C. and take out from the furnace.

11. The method as claimed in claim 10, wherein the anode film manufactured in the step B is manufactured in a continuous manner to form a ribbon which is cut into required size and then treated by reforming and electrochemical protection.
